(19) United States
(12) Patent Application Publication
(10) Pub. No.: US 2012/0199969 A1
(43) Pub. Date: Aug. 9, 2012

(54) SEMICONDUCTOR DEVICE

(76) Inventor: Kenji Yokoyama, Kyoto (JP)

(21) Appl. No.: 13/357,069

(22) Filed: Jan. 24, 2012

(30) Foreign Application Priority Data
Feb. 9, 2011 (JP) 2011-026500

(51) Int. Cl. H01L 23/48

(52) U.S. Cl. 257/737; 257/E23.021

(57) ABSTRACT

A semiconductor device has a semiconductor chip mounted on a circuit board. The semiconductor chip includes: a semiconductor substrate; a first pad formed on the semiconductor substrate; a second pad formed on the first pad via an interlayer insulating film; a via formed through the interlayer insulating film for connecting the first pad with the second pad; a protection film that is formed on the second pad and has an opening exposing a center portion of the second pad; and a barrier metal layer formed on the portion of the second pad exposed from the opening of the protection film and on a portion of the protection film surrounding the opening. The diameter of the via is smaller than the diameter of the opening of the protection film, and the center of the via corresponds with the center of the barrier metal layer.

### CROSS-REFERENCE TO RELATED APPLICATION

This application claims priority to Japanese Patent Application No. 2011-26500 filed on Feb. 9, 2011, the disclosure of which including the specification, the drawings, and the claims is hereby incorporated by reference in its entirety.

### BACKGROUND

The present disclosure relates to a semiconductor device having a semiconductor chip mounted on a circuit board by flip-chip mounting.

As one of methods of mounting a semiconductor chip on a circuit board (e.g., an interposer board), flip-chip mounting is known. In the flip-chip mounting, bumps are formed on pads of a semiconductor chip via barrier metal layers, and the chip is flipped over, so that the pads of the semiconductor chip are electrically connected to lands on an interposer board via the bumps.

### SUMMARY

The semiconductor device having a semiconductor chip mounted on an interposer board by flip-chip mounting described above has the following problem.

In recent years, with speeding up of the operation of semiconductor devices, the current amount flowing through each pad has been increasing. With concentration of the current into a barrier metal layer, electromigration (EM) may occur in the barrier metal layer. This may generate a void in the barrier metal layer, causing rupture of the barrier metal layer.

Techniques for preventing occurrence of EM in bumps and barrier metal layers are proposed (see Japanese Patent Application No. 2007-13063 (Patent Document 1) and Japanese Patent Application No. 2007-208077 (Patent Document 2), for example). In the technique described in Patent Document 1, a plurality of columnar conductors for electrically connecting pads with interconnects are provided, in an attempt to avoid current concentration into bump junctions and thus prevent occurrence of EM in bumps and barrier metal layers. However, in the technique of Patent Document 1, conductors placed at ends, among the plurality of conductors, may rupture due to EM. In this case, the current may concentrate into conductors left without suffering rupture (i.e., conductors placed in the center), among the plurality of conductors. As a result, EM may occur in the barrier metal layers, causing rupture of the barrier metal layers.

In view of the problem described above, it is an objective of the present disclosure to prevent rupture of barrier metal layers that may otherwise occur due to EM.

A first semiconductor device of the present disclosure is a semiconductor device having a semiconductor chip mounted on a circuit board, the semiconductor chip including: a semiconductor substrate; a first pad formed on the semiconductor substrate; a second pad formed on the first pad via an interlayer insulating film; a via formed through the interlayer insulating film for connecting the first pad with the second pad; a protection film formed on the second pad, the protection film having an opening exposing a center portion of the second pad; and a barrier metal layer formed on the portion of the second pad exposed from the opening of the protection film and on a portion of the protection film surrounding the opening, wherein the diameter of the via is smaller than the diameter of the opening of the protection film, and the center of the via corresponds with the center of the barrier metal layer.

In the first semiconductor device of the present disclosure, the via for electrically connecting the first pad with the second pad is provided, and the diameter of such a via is made smaller than the diameter of the opening of the protection film with the center of the via corresponding with the center of the barrier metal layer. With this configuration, since the distance between the side face of the via and the periphery of the barrier metal layer can be increased, concentration of a current into the barrier metal layer can be relieved. Therefore, occurrence of EM in the barrier metal layer can be prevented, and thus rupture of the barrier metal layer that may otherwise occur due to generation of a void can be prevented.

Moreover, occurrence of EM can be prevented, not only in the barrier metal layer, but also in the junction between the barrier metal layer and the bump formed on the barrier metal layer, in the junction between the barrier metal layer and the second pad formed under the barrier metal layer, and in the second pad.

In the first semiconductor device described above, preferably, Wa≦Wb−(Ha+Hb)×2 is satisfied where Wa is the diameter of the via, Wb is the diameter of the opening of the protection film, Ha is the height of the barrier metal layer, and Hb is the height of the protection film.

In the first semiconductor device, preferably, the semiconductor chip further includes a third pad formed on the interlayer insulating film, and multiple ones of the second pad and multiple ones of the third pad are arranged in a matrix on the interlayer insulating film.

In the first semiconductor device, preferably, the second pad is a power supply terminal.

In the first semiconductor device, preferably, a center region of the semiconductor chip is a power supply terminal placement region where power supply terminals are placed, and pad structures each having the first pad, the via, the second pad, and the barrier metal layer are arranged in a matrix in the power supply terminal placement region.

In the first semiconductor device, preferably, a center region of the semiconductor chip is a power supply terminal placement region where power supply terminals are placed, and pad structures each having the first pad, the via, the second pad, and the barrier metal layer are arranged in an outermost peripheral portion of the power supply terminal placement region.

In the first semiconductor device, preferably, a center region of the semiconductor chip is a power supply terminal placement region where power supply terminals are placed, and pad structures each having the first pad, the via, the second pad, and the barrier metal layer are arranged in corners of the power supply terminal placement region.

In the first semiconductor device, preferably, the current values of the second pads are equal to or more than an average current value obtained by averaging the current values of the second pads and the third pads.

In the first semiconductor device, preferably, a bump is formed on the barrier metal layer.

A second semiconductor device of the present disclosure is a semiconductor device having a semiconductor chip mounted on a circuit board, the semiconductor chip including: a semiconductor substrate; an interconnect formed on the semiconductor substrate; a first pad formed on the interconnect via a first interlayer insulating film; a first via formed through the first interlayer insulating film for connecting the interconnect with the first pad; a second pad formed on the first pad via a second interlayer insulating film; a second via formed through the second interlayer insulating film for connecting the first pad with the second pad; a protection film formed on the second pad, the protection film having an opening exposing a center portion of the second pad; and a barrier metal layer formed on the portion of the second pad exposed from the opening of the protection film and on a portion of the protection film surrounding the opening, wherein the diameter of the first via is smaller than the diameter of the opening of the protection film, and the center of the first via corresponds with the center of the barrier metal layer.

In the second semiconductor device of the present disclosure, the second via for electrically connecting the first pad with the second pad and the first via for electrically connecting the interconnect with the first pad are provided, and the diameter of the first via is made smaller than the diameter of the opening of the protection film with the center of the first via corresponding with the center of the barrier metal layer. With this configuration, since the distance between the side face of the first via and the periphery of the barrier metal layer can be increased, concentration of a current into the barrier metal layer can be relieved. Therefore, occurrence of EM in the barrier metal layer can be prevented, and thus rupture of the barrier metal layer that may otherwise occur due to generation of a void can be prevented.

Moreover, occurrence of EM can be prevented, not only in the barrier metal layer, but also in the junction between the barrier metal layer and the bump formed on the barrier metal layer, in the junction between the barrier metal layer and the second pad formed under the barrier metal layer, and in the second pad.

In the second semiconductor device described above, preferably, Wa≦Wb−(Ha+Hb)×2 is satisfied where Wa is the diameter of the first via, Wb is the diameter of the opening of the protection film, Ha is the height of the barrier metal layer, and Hb is the height of the protection film.

In the second semiconductor device, preferably, the diameter of the second via is larger than the diameter of the opening of the protection film, and the center of the second via corresponds with the center of the barrier metal layer.

In the second semiconductor device, preferably, the semiconductor chip further includes a third pad formed on the second interlayer insulating film, and multiple ones of the second pad and multiple ones of the third pad are arranged in a matrix on the second interlayer insulating film.

In the second semiconductor device, preferably, the second pad is a power supply terminal.

In the second semiconductor device, preferably, a center region of the semiconductor chip is a power supply terminal placement region where power supply terminals are placed, and pad structures each having the interconnect, the first via, the first pad, the second via, the second pad, and the barrier metal layer are arranged in a matrix in the power supply terminal placement region.

In the second semiconductor device, preferably, a center region of the semiconductor chip is a power supply terminal placement region where power supply terminals are placed, and pad structures each having the interconnect, the first via, the first pad, the second via, the second pad, and the barrier metal layer are arranged in an outermost peripheral portion of the power supply terminal placement region.

In the second semiconductor device, preferably, a center region of the semiconductor chip is a power supply terminal placement region where power supply terminals are placed, and pad structures each having the interconnect, the first via, the first pad, the second via, the second pad, and the barrier metal layer are arranged in corners of the power supply terminal placement region.

In the second semiconductor device, preferably, the current values of the second pads are equal to or more than an average current value obtained by averaging the current values of the second pads and the third pads.

In the second semiconductor device, preferably, a bump is formed on the barrier metal layer.

As described above, in the semiconductor device of the present disclosure, rupture of the barrier metal layer that may otherwise occur due to EM can be prevented.

### BRIEF DESCRIPTION OF THE DRAWINGS

FIG. 1 is a cross-sectional view showing a configuration of a semiconductor device of a first embodiment of the present disclosure.

FIG. 2 is a plan view showing a configuration of a semiconductor chip of the semiconductor device of the first embodiment.

FIG. 3 is a cross-sectional view taken along line in FIG. 2, showing a configuration of a neighborhood of an upper pad.

FIG. 4 is a cross-sectional view taken along line IV-IV in FIG. 2, showing a configuration of a neighborhood of a pad.

FIG. 5 is a plan view showing a configuration of a semiconductor chip of a semiconductor device of Variation 1 of the first embodiment of the present disclosure.

FIG. 6 is a plan view showing a configuration of a semiconductor chip of a semiconductor device of Variation 2 of the first embodiment of the present disclosure.

FIG. 7 is a plan view showing a configuration of a semiconductor chip of a semiconductor device of a second embodiment of the present disclosure.

FIG. 8 is a cross-sectional view taken along line VIII-VIII in FIG. 7, showing a configuration of a neighborhood of an upper pad.

FIG. 9 is a cross-sectional view taken along line IX-IX in FIG. 7, showing a configuration of a neighborhood of a pad.

FIG. 10 is a plan view showing a configuration of a semiconductor chip of a semiconductor device of Variation 1 of the second embodiment of the present disclosure.

FIG. 11 is a plan view showing a configuration of a semiconductor chip of a semiconductor device of Variation 2 of the second embodiment of the present disclosure.

### DETAILED DESCRIPTION

Embodiments of the present disclosure will be described hereinafter with reference to the accompanying drawings.

### First Embodiment

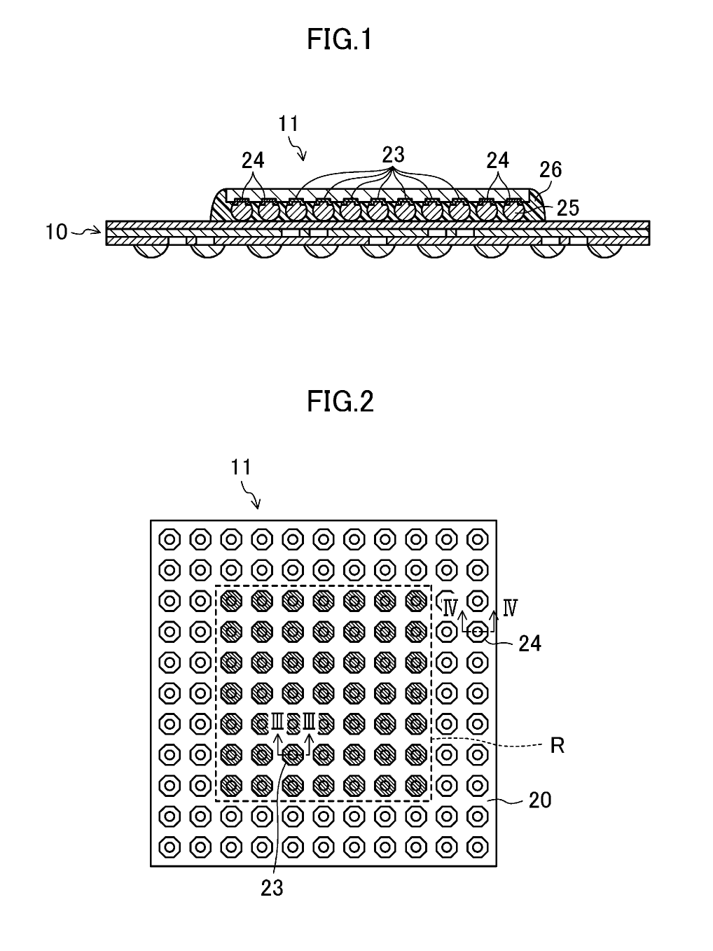

A semiconductor device of the first embodiment of the present disclosure will be described with reference to FIGS. 1 and 2. FIG. 1 is a cross-sectional view of a semiconductor device of the first embodiment, and FIG. 2 is a plan view of a semiconductor chip of the semiconductor device of the first embodiment.

As shown in FIG. 1, a semiconductor chip 11 is mounted on an interposer board 10.

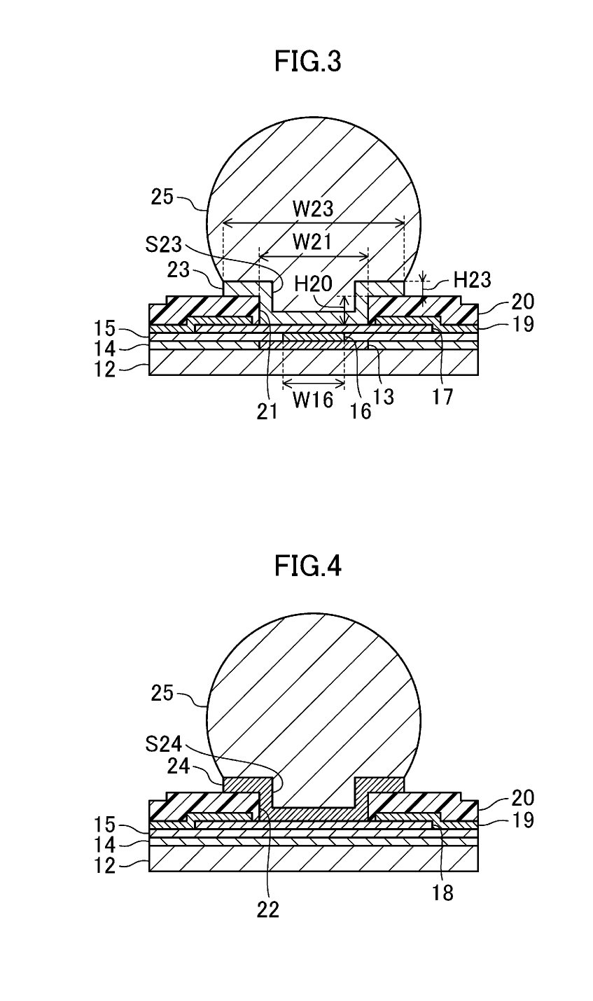

As shown in FIG. 2, barrier metal layers 23 and 24 are arranged in a matrix in the semiconductor chip 11. As will be described in detail with reference to FIG. 3, each barrier metal layer 23 is formed on a center portion of an upper pad (17 in FIG. 3) and on a portion of a protection film 20 surrounding an opening (21 in FIG. 3) thereof. Similarly, as will be described in detail with reference to FIG. 4, each barrier metal layer 24 is formed on a center portion of a pad (18 in FIG. 4) and on a portion of the protection film 20 surrounding an opening (22 in FIG. 4) thereof. The shape o in each barrier metal layer 23 shown in FIG. 2 represents the inner wall S23 of the barrier metal layer 23 as will be described with reference to FIG. 3. Similarly, the shape o in each barrier metal layer 24 shown in FIG. 2 represents the inner wall S24 of the barrier metal layer 24 as will be described with reference to FIG. 4.

As shown in FIG. 2, the barrier metal layers 23 are arranged in a matrix in a center region of the semiconductor chip 11 that is a power supply terminal placement region R where power supply terminals are placed. The upper pads (17 in FIG. 3) formed under the barrier metal layers 23 are power supply terminals.

As shown in FIG. 2, the planar shape of the barrier metal layers 23 and 24 is octagonal, for example. The planar shape of the inner wall (S23 in FIG. 3) of each barrier metal layer 23 and the inner wall (S24 in FIG. 4) of each barrier metal layer 24 is circular, for example, and thus the openings (21 in FIGS. 3 and 22 in FIG. 4) are circular.

Lands (not shown) are arranged in a matrix on the surface of the interposer board 10. As shown in FIG. 1, bumps 25 are placed between the barrier metal layers 23 and 24 and the lands: the bumps 25 placed between the barrier metal layers 23 and the lands electrically connect the upper pads with the lands, and the bumps 25 placed between the barrier metal layers 24 and the lands electrically connect the pads with the lands. Space between the interposer board 10 and the semiconductor chip 11 is filled with an underfill resin 26.

The configurations of a neighborhood of an upper pad and a neighborhood of a pad will be described hereinafter with reference to FIGS. 3 and 4. FIG. 3 is an enlarged cross-sectional view taken along line in FIG. 2, showing a neighborhood of an upper pad, and FIG. 4 is an enlarged cross-sectional view taken along line IV-IV in FIG. 2, showing a neighborhood of a pad

As shown in FIGS. 3 and 4, interlayer insulating films 14 and 15 are formed sequentially on a semiconductor substrate 12.

As shown in FIG. 3, a lower pad 13 is formed on the semiconductor substrate 12 to be surrounded by the interlayer insulating film 14. The upper pad 17 is formed on the lower pad 13 via the interlayer insulating film 15. A via 16 is formed through the interlayer insulating film 15, so that the lower pad 13 and the upper pad 17 are electrically connected to each other via the via 16.

As shown in FIG. 4, the pad 18 is formed on the interlayer insulating film 15.

As shown in FIGS. 3 and 4, a protection film 19 having an opening exposing a center portion of the upper pad 17 and an opening exposing a center portion of the pad 18 is formed to cover the interlayer insulating film 15 and the peripheries of the upper pad 17 and the pad 18. The protection film 19 is a nitride film, for example. On the protection film 19, a protection film 20 having the opening 21 exposing a center portion of the upper pad 17 and the opening 22 exposing a center portion of the pad 18 is formed. The protection film 20 is made of a resin, for example.

As shown in FIG. 3, the barrier metal layer 23 is formed on the portion of the upper pad 17 exposed from the opening 21 of the protection film 20 (i.e., a center portion of the upper pad 17) and on a portion of the protection film 20 surrounding the opening 21. A bump 25 is formed on the barrier metal layer 23.

As shown in FIG. 4, the barrier metal layer 24 is formed on the portion of the pad 18 exposed from the opening 22 of the protection film 20 (i.e., a center portion of the pad 18) and on a portion of the protection film 20 surrounding the opening 22. A bump 25 is formed on the barrier metal layer 24.

As is found from FIGS. 1-4, the semiconductor chip 11 includes the semiconductor substrate 12, the interlayer insulating films 14 and 15, the lower pads 13, the vias 16, the upper pads 17, the pads 18, the protection films 19 and 20, the barrier metal layers 23 and 24, and the bumps 25.

Pad structures (see FIG. 3) each including the barrier metal layer 23 are arranged in a matrix in the center region (i.e., the power supply terminal placement region R) of the semiconductor chip 11 as shown in FIG. 2. Each of the barrier metal-including pad structures includes the lower pad 13, the via 16, and the upper pad 17, in addition to the barrier metal layer 23, as shown in FIG. 3.

In a peripheral region of the semiconductor chip 11, pad structures (see FIG. 4) each including the barrier metal layer 24 are arranged in a matrix. Each of the barrier metal-including pad structures includes the pad 18 in addition to the barrier metal layer 24 as shown in FIG. 4.

As shown in FIG. 3, the diameter W21 of the opening 21 of the protection film 20 is smaller than the diameter W23 of the barrier metal layer 23 (W21<W23), and the diameter W16 of the via 16 is smaller than the diameter W21 of the opening 21 of the protection film 20 (W16<W21). The center of the via 16 corresponds with the center of the barrier metal layer 23 and the center of the opening 21 of the protection film 20.

Here, the diameter W16 of the via 16 satisfies

Wa=Wb−(Ha+Hb)×2

where Wa is the diameter W16 of the via 16, Wb is the diameter W21 of the opening 21 of the protection film 20, Ha is the height H23 of the barrier metal layer 23, and Hb is the height H20 of the protection film 20.

The “height H23 of the barrier metal layer 23” refers to the height from the bottom to the top of the peripheral portion of the barrier metal layer 23, which is the portion of the barrier metal layer 23 formed on the protection film 20, as shown in FIG. 3. The “height H20 of the protection film 20” refers to the height from the bottom to the top of the portion of the protection film 20 exposed from the opening 21 of the protection film 20 as shown in FIG. 3.

In this embodiment, the via 16 for electrically connecting the lower pad 13 with the upper pad 17 is provided, and the diameter W16 of the via 16 is made smaller than the diameter W21 of the opening 21 of the protection film 20 with the center of the via 16 corresponding with the center of the barrier metal layer 23. With this configuration, since the distance between the side face of the via 16 and the periphery of the barrier metal layer 23 can be increased, concentration of a current into the barrier metal layer 23 can be relieved. Therefore, occurrence of EM in the barrier metal layer 23 can be prevented, and thus rupture of the barrier metal layer 23 that may otherwise occur due to generation of a void can be prevented.

As described above, in this embodiment, the via 16 for electrically connecting the lower pad 13 with the upper pad 17 is provided under the barrier metal layer 23 in which it is expected that EM is likely to occur (i.e., a barrier metal layer formed on a power supply terminal large in current amount (the upper pad 17)), and the diameter W16 of the via 16 is made smaller than the diameter W21 of the opening 21 of the protection film 20. Having such a via, occurrence of EM in the barrier metal layer 23 can be prevented.

Occurrence of EM can be prevented, not only in the barrier metal layer 23, but also in the junction between the barrier metal layer 23 and the bump 25 formed on the barrier metal layer 23, in the junction between the barrier metal layer 23 and the upper pad 17 formed under the barrier metal layer 23, and in the upper pad 17.

Although the case that the upper pad 17 is a power supply terminal (power supply pad) is described as a specific example in this embodiment, the present disclosure is not limited to this. The upper pad 17 may be any terminal large in current amount, preferably, such as an analog pad and a clock signal pad.

Although the case that Wa=Wb−(Ha+Hb)×2 is satisfied is described as a specific example in this embodiment, the present disclosure is not limited to this. For example, Wa<Wb−(Ha+Hb)×2 may be satisfied. In other words, it is preferable that Wa≦Wb−(Ha+Hb)×2 is satisfied. Under this condition, concentration of a current into the via 16 can be avoided. Note however that it is not necessarily required to satisfy Wa≦Wb−(Ha+Hb)×2.

### Variation 1 of First Embodiment

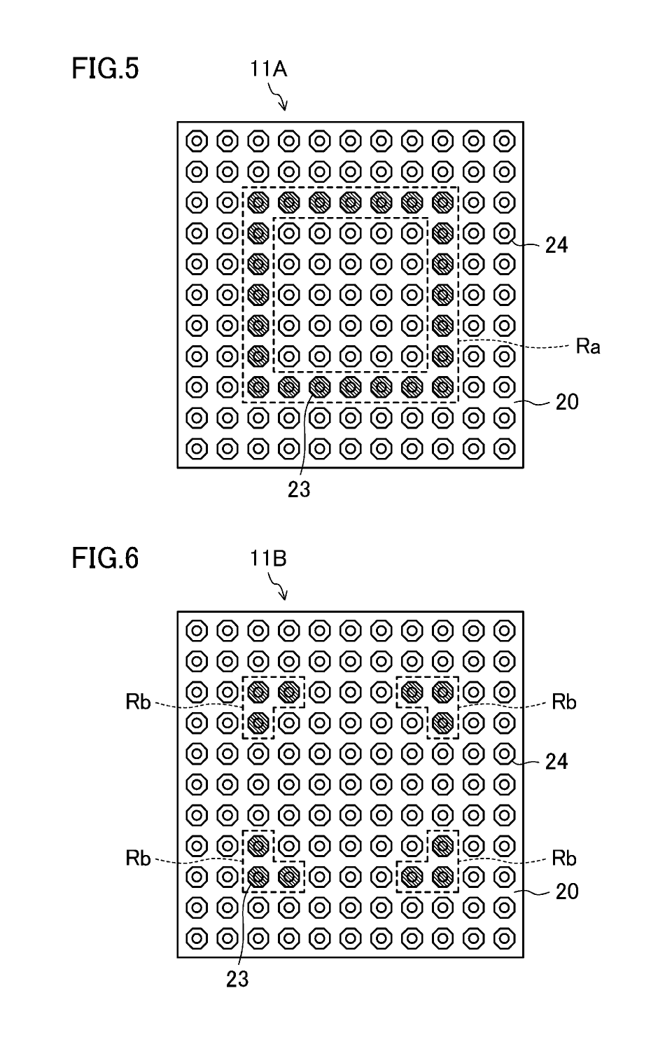

A semiconductor device of Variation 1 of the first embodiment of the present disclosure will be described hereinafter with reference to FIG. 5. FIG. 5 is a plan view of a semiconductor chip 11A of the semiconductor device of Variation 1 of the first embodiment. In this variation, similar components to those in the first embodiment are denoted by similar reference numerals, and description of such components is omitted as appropriate in this variation.

This variation is different from the first embodiment described above in the following point.

In the first embodiment, the pad structures each including the barrier metal layer 23 (see FIG. 3) are arranged in a matrix in the power supply terminal placement region R (i.e., the center region of the semiconductor chip 11) as shown in FIG. 2.

In this variation, as shown in FIG. 5, the pad structures each including the barrier metal layer 23 are arranged in an outermost peripheral portion Ra of the power supply terminal placement region (i.e., the center region of the semiconductor chip 11A).

Although the pad structures are arranged in one row to form the outermost peripheral portion Ra of the power supply terminal placement region in this variation, the present disclosure is not limited to this. For example, pad structures in two or more rows may be arranged along the periphery of the power supply terminal placement region.

### Variation 2 of First Embodiment

A semiconductor device of Variation 2 of the first embodiment of the present disclosure will be described hereinafter with reference to FIG. 6. FIG. 6 is a plan view of a semiconductor chip 11B of the semiconductor device of Variation 2 of the first embodiment. In this variation, similar components to those in the first embodiment are denoted by similar reference numerals, and description of such components is omitted as appropriate in this variation.

This variation is different from the first embodiment described above in the following point.

In the first embodiment, the pad structures each including the barrier metal layer 23 (see FIG. 3) are arranged in a matrix in the power supply terminal placement region R (i.e., the center region of the semiconductor chip 11) as shown in FIG. 2.

In this variation, as shown in FIG. 6, the pad structures each including the barrier metal layer 23 are arranged in corners Rb of the power supply terminal placement region (i.e., the center region of the semiconductor chip 11B).

In the first embodiment and Variations 1 and 2 thereof, specific examples of placing the pad structures each including the barrier metal layer 23 and the upper pad formed under the barrier metal layer 23 in specific portions of the semiconductor chip (i.e., in the center region of the semiconductor chip 11 in the first embodiment, in the outermost portion of the center region of the semiconductor chip 11A in Variation 1, and in the corners of the center region of the semiconductor chip 11B in Variation 2). The present disclosure is not limited to this. For example, any terminal having a current value equal to or more than the average current value of all terminals may be made to serve as the upper pad, while any terminal having a current value less than the average current value may be made to serve as the pad, so that pad structures each including the upper pad and the barrier metal layer formed on the upper pad may be arranged at random in the semiconductor chip. The “average current value of all terminals” refers to the current value obtained by averaging the current values of the upper pads and the current values of the pads.

### Second Embodiment

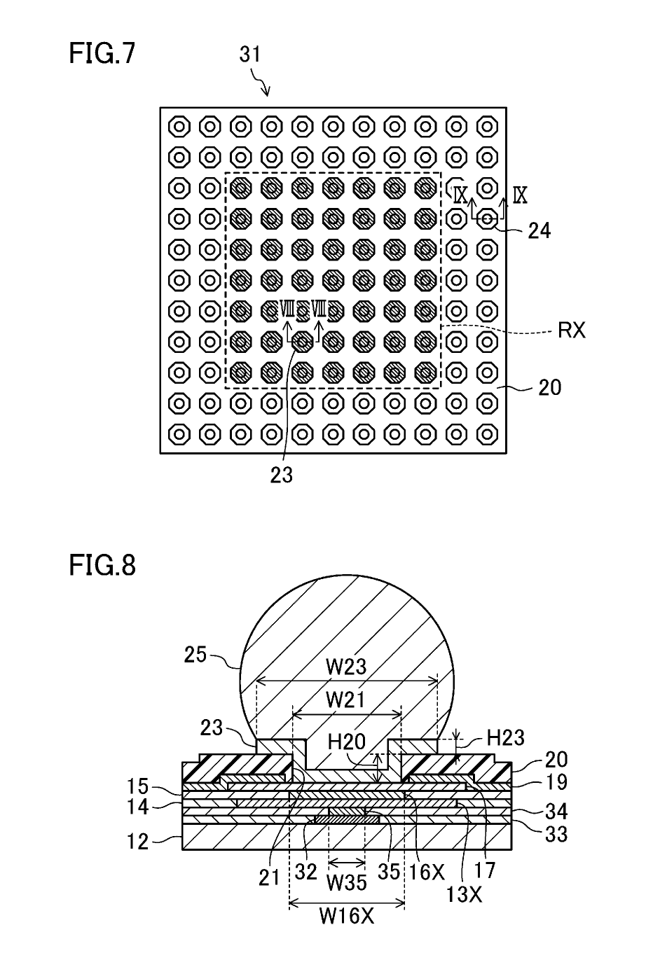

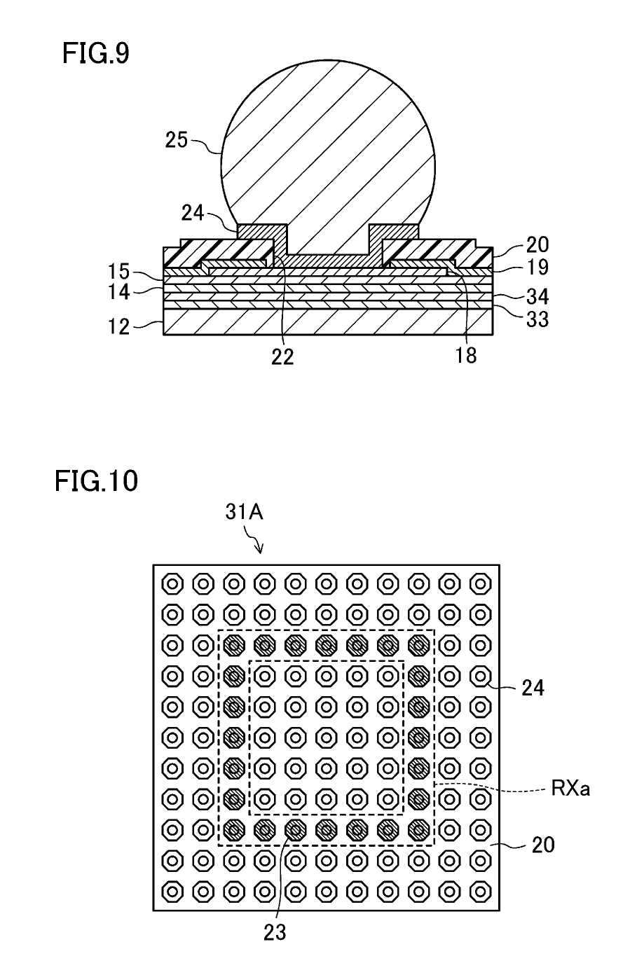

A semiconductor device of the second embodiment of the present disclosure will be described with reference to FIGS. 7-9. FIG. 7 is a plan view of a semiconductor chip 31 of the semiconductor device of the second embodiment. FIG. 8 is an enlarged cross-sectional view taken along line VIII-VIII in FIG. 7, showing a neighborhood of an upper pad, and FIG. 9 is an enlarged cross-sectional view taken along line IX-IX in FIG. 7, showing a neighborhood of a pad. In this embodiment, similar components to those in the first embodiment are denoted by similar numerals, and description of such components is omitted as appropriate in this embodiment.

As shown in FIG. 7, barrier metal layers 23 are arranged in a matrix in a center region of the semiconductor chip 31 that is a power supply terminal placement region RX. Upper pads (17 in FIG. 8) formed under the barrier metal layers 23 are power supply terminals.

As shown in FIGS. 8 and 9, interlayer insulating films 33, 34, 14, and 15 are formed sequentially on a semiconductor substrate 12.

As shown in FIG. 8, an interconnect 32 is formed on the semiconductor substrate 12 to be surrounded by the interlayer insulating film 33. A lower pad 13X is formed on the interconnect 32 via the interlayer insulating film 34 to be surrounded by the interlayer insulating film 14. A via 35 is formed through the interlayer insulating film 34, so that the interconnect 32 and the lower pad 13X are electrically connected to each other via the via 35.

The upper pad 17 is formed on the lower pad 13X via the interlayer insulating film 15. A via 16X is formed through the interlayer insulating film 15, so that the lower pad 13X and the upper pad 17 are electrically connected to each other via the via 16X.

As shown in FIG. 9, a pad 18 is formed on the interlayer insulating film 15.

As is found from FIGS. 7-9, the semiconductor chip 31 includes the semiconductor substrate 12, the interlayer insulating films 33, 34, 14, and 15, the interconnects 32, the vias 35, the lower pads 13X, the vias 16X, the upper pads 17, the pads 18, protection films 19 and 20, barrier metal layers 23 and 24, and bumps 25.

As shown in FIG. 7, in the center region (i.e., the power supply terminal placement region RX) of the semiconductor chip 31, pad structures (see FIG. 8) each including the barrier metal layer 23 are arranged in a matrix. Each of the barrier metal-including pad structures includes the interconnect 32, the via 35, the lower pad 13X, the via 16X, and the upper pad 17, in addition to the barrier metal layer 23, as shown in FIG. 8.

In a peripheral region of the semiconductor chip 31, pad structures (see FIG. 9) each including the barrier metal layer 24 are arranged in a matrix. Each of the barrier metal-including pad structures includes the pad 18 in addition to the barrier metal layer 24 as shown in FIG. 9.

As shown in FIG. 8, the diameter W21 of an opening 21 of the protection film 20 is smaller than the diameter W23 of the barrier metal layer 23 (W21<W23), and the diameter W16X of the via 16X is larger than the diameter W21 of the opening 21 of the protection film 20 (W16X>W21). Also, the diameter W35 of the via 35 is smaller than the diameter W21 of the opening 21 of the protection film 20 (W35<W21). The centers of the vias 16X and 35 correspond with the center of the barrier metal layer 23 and the center of the opening 21 of the protection film 20.

Here, the diameter W35 of the via 35 satisfies

Wax=Wb−(Ha+Hb)×2

where Wax is the diameter W35 of the via 35, Wb is the diameter W21 of the opening 21 of the protection film 20, Ha is the height H23 of the barrier metal layer 23, and Hb is the height H20 of the protection film 20.

In this embodiment, the via 16X for electrically connecting the lower pad 13X with the upper pad 17 and the via 35 for electrically connecting the interconnect 32 with the lower pad 13X are provided, and the diameter W35 of the via 35 is made smaller than the diameter W21 of the opening 21 of the protection film 20 with the center of the via 35 corresponding with the center of the barrier metal layer 23. With this configuration, since the distance between the side face of the via 35 and the periphery of the barrier metal layer 23 can be increased, concentration of a current into the barrier metal layer 23 can be relieved. Therefore, occurrence of EM in the barrier metal layer 23 can be prevented, and thus rupture of the barrier metal layer 23 that may otherwise occur due to generation of a void can be prevented.

As described above, in this embodiment, the via 16X for electrically connecting the lower pad 13X with the upper pad 17 and the via 35 for electrically connecting the interconnect 32 with the lower pad 13X are provided under the barrier metal layer 23 in which it is expected that EM is likely to occur, and the diameter W35 of the via 35 is made smaller than the diameter W21 of the opening 21 of the protection film 20. Having such vias, occurrence of EM in the barrier metal layer 23 can be prevented.

Occurrence of EM can be prevented, not only in the barrier metal layer 23, but also in the junction between the barrier metal layer 23 and the bump 25 formed on the barrier metal layer 23, in the junction between the barrier metal layer 23 and the upper pad 17 formed under the barrier metal layer 23, and in the upper pad 17.

Although the case that the upper pad 17 is a power supply terminal (power supply pad) is described as a specific example in this embodiment, the present disclosure is not limited to this. The upper pad may be any terminal large in current amount, preferably, such as an analog pad and a clock signal pad.

Although the case that Wax=Wb−(Ha+Hb)×2 is satisfied is described as a specific example in this embodiment, the present disclosure is not limited to this. For example, Wax<Wb−(Ha+Hb)×2 may be satisfied. In other words, it is preferable that Wax≦Wb−(Ha+Hb)×2 is satisfied. Under this condition, concentration of a current into the via 35 can be avoided. Note however that it is not necessarily required to satisfy Wax≦Wb−(Ha+Hb)×2.

### Variation 1 of Second Embodiment

A semiconductor device of Variation 1 of the second embodiment of the present disclosure will be described hereinafter with reference to FIG. 10. FIG. 10 is a plan view of a semiconductor chip 31A of the semiconductor device of Variation 1 of the second embodiment. In this variation, similar components to those in the second embodiment are denoted by similar numerals, and description of such components is omitted as appropriate in this variation.

This variation is different from the second embodiment described above in the following point.

In the second embodiment, the pad structures each including the barrier metal layer 23 (see FIG. 8) are arranged in a matrix in the power supply terminal placement region RX (i.e., the center region of the semiconductor chip 31) as shown in FIG. 7.

In this variation, as shown in FIG. 10, the pad structures each including the barrier metal layer 23 are arranged in an outermost peripheral portion RXa of the power supply terminal placement region (i.e., the center region of the semiconductor chip 31A). Although the pad structures are arranged in one row to form the outermost peripheral portion RXa of the power supply terminal placement region in this variation, the present disclosure is not limited to this. For example, pad structures in two or more rows may be arranged along the periphery of the power supply terminal placement region.

### Variation 2 of Second Embodiment 2

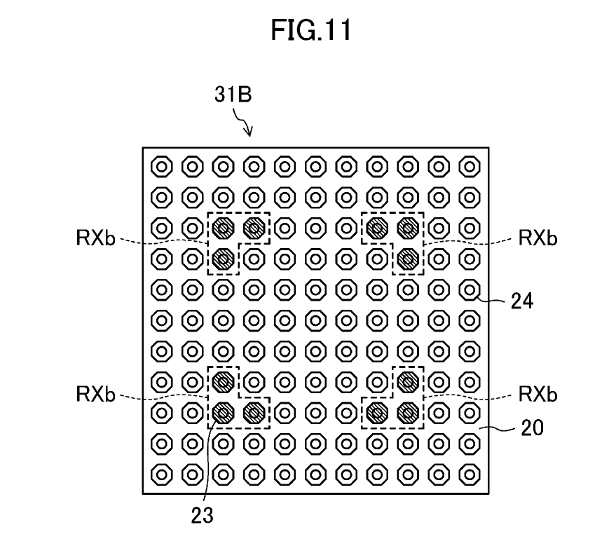

A semiconductor device of Variation 2 of the second embodiment of the present disclosure will be described hereinafter with reference to FIG. 11. FIG. 11 is a plan view showing a configuration of a semiconductor chip 31B of the semiconductor device of Variation 2 of the second embodiment. In this variation, similar components to those in the second embodiment are denoted by similar reference numerals, and description of such components is omitted as appropriate in this variation.

This variation is different from the second embodiment described above in the following point.

In the second embodiment, the pad structures each including the barrier metal layer 23 (see FIG. 8) are arranged in a matrix in the power supply terminal placement region RX (i.e., the center region of the semiconductor chip 31) as shown in FIG. 7.

In this variation, as shown in FIG. 11, the pad structures each including the barrier metal layer 23 are arranged in corners RXb of the power supply terminal placement region (i.e., the center region of the semiconductor chip 31B).

In the second embodiment and Variations 1 and 2 thereof, specific examples of placing the pad structures each including the barrier metal layer 23 and the upper pad formed under the barrier metal layer 23 in specific portions of the semiconductor chip (i.e., in the center region of the semiconductor chip 31 in the second embodiment, in the outermost portion of the center region of the semiconductor chip 31A in Variation 1, and in the corners of the center region of the semiconductor chip 31B in Variation 2). The present disclosure is not limited to this. For example, any terminal having a current value equal to or more than the average current value of all terminals may be made to serve as the upper pad, while any terminal having a current value less than the average current value may be made to serve as the pad, so that pad structures each including the upper pad and the barrier metal layer formed on the upper pad may be arranged at random in the semiconductor chip.

In the first and second embodiments and Variations 1 and 2 thereof, described were specific cases of using the interposer board 10 as the circuit board on which the semiconductor chips 11, 11A, 11B, 31, 31A, and 31B are mounted. The present disclosure is not limited to this, but a resin substrate, a silicon substrate, or a flexible substrate, for example, may be used in place of the interposer board 10.

It is to be understood that the first and second embodiments and Variations 1 and 2 thereof described above are mere examples of the present disclosure and are not intended to restrict the disclosure. Various modifications and changes to the present disclosure may be made without departing from the spirit of the present disclosure, and such modifications and changes are also included in the scope of the present disclosure. The first and second embodiments and Variations 1 and 2 thereof may be combined as appropriate to carry out the present disclosure without departing from the spirit of the present disclosure.

As described above, the present disclosure, providing the advantage of preventing EM-caused rapture of barrier metal layers, is applicable to a semiconductor device in which pads of a semiconductor chip and lands of a circuit board are electrically connected to each other with bumps formed on the pads via the barrier metal layers.

What is claimed is:

1. A semiconductor device having a semiconductor chip mounted on a circuit board, the semiconductor chip comprising:
a semiconductor substrate;
a first pad formed on the semiconductor substrate;
a second pad formed on the first pad via an interlayer insulating film;
a via formed through the interlayer insulating film for connecting the first pad with the second pad;
a protection film formed on the second pad, the protection film having an opening exposing a center portion of the second pad; and
a barrier metal layer formed on the portion of the second pad exposed from the opening of the protection film and on a portion of the protection film surrounding the opening,
wherein
a diameter of the via is smaller than a diameter of the opening of the protection film, and
a center of the via corresponds with a center of the barrier metal layer.

2. The device of claim 1, wherein
Wa≦Wb−(Ha+Hb)×2
is satisfied where Wa is the diameter of the via, Wb is the diameter of the opening of the protection film, Ha is a height of the barrier metal layer, and Hb is a height of the protection film.

3. The device of claim 1, wherein
the semiconductor chip further includes a third pad formed on the interlayer insulating film, and
multiple ones of the second pad and multiple ones of the third pad are arranged in a matrix on the interlayer insulating film.

4. The device of claim 1, wherein
the second pad is a power supply terminal.

5. The device of claim 4, wherein
a center region of the semiconductor chip is a power supply terminal placement region where power supply terminals are placed, and
pad structures each having the first pad, the via, the second pad, and the barrier metal layer are arranged in a matrix in the power supply terminal placement region.

6. The device of claim 4, wherein
a center region of the semiconductor chip is a power supply terminal placement region where power supply terminals are placed, and
pad structures each having the first pad, the via, the second pad, and the barrier metal layer are arranged in an outermost peripheral portion of the power supply terminal placement region.

7. The device of claim 4, wherein
a center region of the semiconductor chip is a power supply terminal placement region where power supply terminals are placed, and
pad structures each having the first pad, the via, the second pad, and the barrier metal layer are arranged in corners of the power supply terminal placement region.

8. The device of claim 3, wherein
current values of the second pads are equal to or more than an average current value obtained by averaging current values of the second pads and the third pads.

9. The device of claim 1, wherein
a bump is formed on the barrier metal layer.

10. A semiconductor device having a semiconductor chip mounted on a circuit board, the semiconductor chip comprising:
a semiconductor substrate;
an interconnect formed on the semiconductor substrate;
a first pad formed on the interconnect via a first interlayer insulating film;
a first via formed through the first interlayer insulating film for connecting the interconnect with the first pad;
a second pad formed on the first pad via a second interlayer insulating film;
a second via formed through the second interlayer insulating film for connecting the first pad with the second pad;
a protection film formed on the second pad, the protection film having an opening exposing a center portion of the second pad; and
a barrier metal layer formed on the portion of the second pad exposed from the opening of the protection film and on a portion of the protection film surrounding the opening,
wherein
a diameter of the first via is smaller than a diameter of the opening of the protection film, and
a center of the first via corresponds with a center of the barrier metal layer.

11. The device of claim 10, wherein
Wa≦Wb−(Ha+Hb)×2
is satisfied where Wa is the diameter of the first via, Wb is the diameter of the opening of the protection film, Ha is a height of the barrier metal layer, and Hb is a height of the protection film.

12. The device of claim 10, wherein
a diameter of the second via is larger than the diameter of the opening of the protection film, and
a center of the second via corresponds with the center of the barrier metal layer.

13. The device of claim 10, wherein
the semiconductor chip further includes a third pad formed on the second interlayer insulating film, and
multiple ones of the second pad and multiple ones of the third pad are arranged in a matrix on the second interlayer insulating film.

14. The device of claim 10, wherein
the second pad is a power supply terminal.

15. The device of claim 14, wherein
a center region of the semiconductor chip is a power supply terminal placement region where power supply terminals are placed, and
pad structures each having the interconnect, the first via, the first pad, the second via, the second pad, and the barrier metal layer are arranged in a matrix in the power supply terminal placement region.

16. The device of claim 14, wherein
a center region of the semiconductor chip is a power supply terminal placement region where power supply terminals are placed, and
pad structures each having the interconnect, the first via, the first pad, the second via, the second pad, and the barrier metal layer are arranged in an outermost peripheral portion of the power supply terminal placement region.

17. The device of claim 14, wherein
a center region of the semiconductor chip is a power supply terminal placement region where power supply terminals are placed, and
pad structures each having the interconnect, the first via, the first pad, the second via, the second pad, and the barrier metal layer are arranged in corners of the power supply terminal placement region.

18. The device of claim 13, wherein current values of the second pads are equal to or more than an average current value obtained by averaging current values of the second pads and the third pads.

19. The device of claim 10, wherein
a bump is formed on the barrier metal layer.
